(19) United States
(12) Patent Application Publication
(10) Pub. No.: US 2023/0170262 A1
(43) Pub. Date: Jun. 1, 2023

(54) INTEGRATION MANUFACTURING METHOD OF HIGH VOLTAGE DEVICE AND LOW VOLTAGE DEVICE

(71) Applicant: RICHTEK TECHNOLOGY CORPORATION, Zhubei City (TW)

(72) Inventors: Chih-Wen Hsiung, Hsinchu (TW); Wu-Te Weng, Hsinchu (TW); Ta-Yung Yang, Taoyuan (TW)

(21) Appl. No.: 17/858,167

(22) Filed: Jul. 6, 2022

Related U.S. Application Data
(60) Provisional application No. 63/264,768, filed on Dec. 1, 2021.

(30) Foreign Application Priority Data
Mar. 9, 2022 (TW) 111108514

(51) Int. Cl. H01L 21/8234

(52) U.S. Cl. CPC H01L 21/823493; H01L 21/823456

(57) ABSTRACT

An integration manufacturing method of a high voltage device and a low voltage device includes: providing a substrate; forming a semiconductor layer on the substrate; forming insulation regions on the semiconductor layer, for defining a high voltage device region and a low voltage device region; forming a first high voltage well in the high voltage device region; forming a second high voltage well in the semiconductor layer, wherein the first high voltage well and the second high voltage well are in contact with each other in a channel direction; forming an oxide layer on the semiconductor layer, wherein the oxide layer overlays the high voltage device region and the low voltage device region; and forming a first low voltage well in the low voltage device region in the semiconductor layer.

### CROSS REFERENCE

The present invention claims priority to U.S. 63/264,768 filed on Dec. 1, 2021 and claims priority to TW 111108514 filed on Mar. 9, 2022.

### BACKGROUND OF THE INVENTION

### Field of Invention

The present invention relates to an integration manufacturing method of a high voltage device and a low voltage device; particularly, it relates to such integration manufacturing method of a high voltage device and a low voltage device capable of forming a sacrificial oxide layer of a low voltage well in the low voltage device when forming an oxide layer of a reduced surface field (RESURF) oxide region in the high voltage device.

### Description of Related Art

In a conventional manufacturing method for a low voltage device, prior to the formation of a low voltage well, a sacrificial oxide layer is formed, to serve as a block layer for ion implantation during an ion implantation process step for forming the low voltage well, thereby preventing a semiconductor layer from being directly bombarded, so that no defect will occur in the semiconductor layer.

The sacrificial oxide layer is formed by a thermal oxide process step wherein a thermal budget should be taken into consideration. It is vital for an integration process of a semiconductor device to control the thermal budget. As the size of the semiconductor device becomes even smaller, it is imperative to control the thermal budget.

In view of the above, the present invention proposes an integration manufacturing method of a high voltage device and a low voltage device with reduced thermal budget, so as to precisely control the contour of impurities doped in the semiconductor device.

### SUMMARY OF THE INVENTION

From one perspective, the present invention provides an integration manufacturing method of a high voltage device and a low voltage device, comprising: providing a substrate; forming a semiconductor layer on the substrate; forming a plurality of insulation regions on the semiconductor layer, for defining a high voltage device region and a low voltage device region; forming a first high voltage well having a first conductivity type in the high voltage device region in the semiconductor layer, wherein a part of the first high voltage well defines a drift region, which serve as a drift current channel in an ON operation of the high voltage device; forming a second high voltage well having a second conductivity type in the semiconductor layer, wherein the first high voltage well and the second high voltage well are in contact with each other in a channel direction; wherein the second high voltage well has a first portion and a second portion, wherein the first portion is located in the high voltage device region, and the second portion is located between the high voltage device region and the low voltage device region; subsequent to the formation of the first high voltage well and the second high voltage well, forming an oxide layer on the semiconductor layer, wherein the oxide layer overlays the high voltage device region and the low voltage device region; and subsequent to the formation of the oxide layer, forming a first low voltage well in the low voltage device region in the semiconductor layer; wherein the first low voltage well is formed by implanting impurities in a defined region of the first low voltage well in a form of accelerated ions which penetrate the oxide layer.

In one embodiment, the integration manufacturing method of the high voltage device and the low voltage device further comprises: forming a buried layer in the high voltage device region in the substrate, wherein the buried layer has the first conductivity type; and forming a deep well in the semiconductor layer, wherein the deep well has the first conductivity type, and wherein the deep well is in contact with the plurality of insulation regions and the buried layer which define the high voltage device region; wherein the second portion of the second high voltage well, the buried layer and the deep well constitute an isolation region, which serves to electrically isolate the high voltage device region from the low voltage device region in the semiconductor layer.

In one embodiment, the integration manufacturing method of the high voltage device and the low voltage device further comprises: subsequent to the formation of the first low voltage well, etching the oxide layer to form a reduced surface field (RESURF) oxide region in the high voltage device region; subsequent to the formation of the RESURF oxide region, forming a gate oxide layer on the semiconductor layer, wherein the gate oxide layer is in contact with the semiconductor layer, wherein the gate oxide layer overlays the high voltage device region and the low voltage device region; forming a polysilicon layer on the gate oxide layer, wherein the polysilicon layer is in contact with the gate oxide layer; and forming a body region in the high voltage device region in the semiconductor layer, wherein the body region and the first high voltage well are in contact with each other in the channel direction.

In one embodiment, the integration manufacturing method of the high voltage device and the low voltage device further comprises: etching the polysilicon layer to form a high voltage gate in the high voltage device region and a first low voltage gate in the low voltage device region.

In one embodiment, the integration manufacturing method of the high voltage device and the low voltage device further comprises: forming a high voltage source and a high voltage drain in the semiconductor layer, wherein the high voltage source and the high voltage drain are located below and outside two sides of the high voltage gate respectively, wherein the side of the high voltage gate which is closer to the high voltage source is a source side and the side of the high voltage gate which is closer to the high voltage drain is a drain side, and wherein the high voltage source is located in the body region, and the high voltage drain is located in the first high voltage well outside the drain side; and wherein in the channel direction, the drift region is located in the first high voltage well between the high voltage drain and the body region, wherein each of the high voltage source and the high voltage drain has the first conductivity type.

In one embodiment, the integration manufacturing method of the high voltage device and the low voltage device further comprises: forming a first low voltage source and a first low voltage drain in the low voltage device region in the semiconductor layer, wherein the first low voltage source and the first low voltage drain are located below and outside two sides of the low voltage gate respectively, wherein the side of the low voltage gate which is closer to the first low voltage source is a source side and the side of the low voltage gate which is closer to the first low voltage drain is a drain side, and wherein the first low voltage source is located in the first low voltage well, and the first low voltage drain is located in the first low voltage well outside the drain side.

In one embodiment, the integration manufacturing method of the high voltage device and the low voltage device further comprises: forming a second low voltage source and a second low voltage drain in the semiconductor layer, wherein the second low voltage source and the second low voltage drain are located below and outside two sides of the low voltage gate respectively, wherein the side of the low voltage gate which is closer to the second low voltage source is a source side and the side of the low voltage gate which is closer to the second low voltage drain is a drain side, and wherein the second low voltage source is located in the second low voltage well, and the second low voltage drain is located in a second low voltage well outside the drain side.

In one embodiment, the low voltage device region includes a first low voltage device and a second low voltage device; wherein the first low voltage device includes: the first low voltage well, the first low voltage gate, the first low voltage source and the first low voltage drain; wherein the second low voltage device includes: the second low voltage well, the second low voltage gate, the second low voltage source and the second low voltage drain; wherein the first low voltage well and the second low voltage well are in contact with each other in the channel direction; wherein the first low voltage device and the second low voltage device have conductivity types opposite to each other; wherein the second low voltage source, the second low voltage drain, the high voltage source and the high voltage drain are formed at the same time via one same ion implantation process step.

In one embodiment, the semiconductor layer is a P-type semiconductor epitaxial layer having a volume resistance of 45 Ohm-cm.

In one embodiment, the RESURF oxide region has a thickness ranging between 400 Å and 450 Å.

In one embodiment, the gate oxide layer has a thickness ranging between 80 Å and 100 Å.

In one embodiment, a gate driving voltage of a high voltage device in the high voltage device region is 3.3V.

In one embodiment, the body region is formed via a self-alignment process step.

In one embodiment, each of the first low voltage gate and the second low voltage gate has a length greater than or equal to 0.18 micrometer, and wherein each of the first low voltage device and the second low voltage device has a minimum feature size of 0.18 micrometer.

The objectives, technical details, features, and effects of the present invention will be better understood with regard to the detailed description of the embodiments below, with reference to the attached drawings.

### BRIEF DESCRIPTION OF THE DRAWINGS

FIG. 1A to FIG. 1G show a first embodiment of the present invention.

FIG. 2A to FIG. 2M shows a second embodiment of the present invention.

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

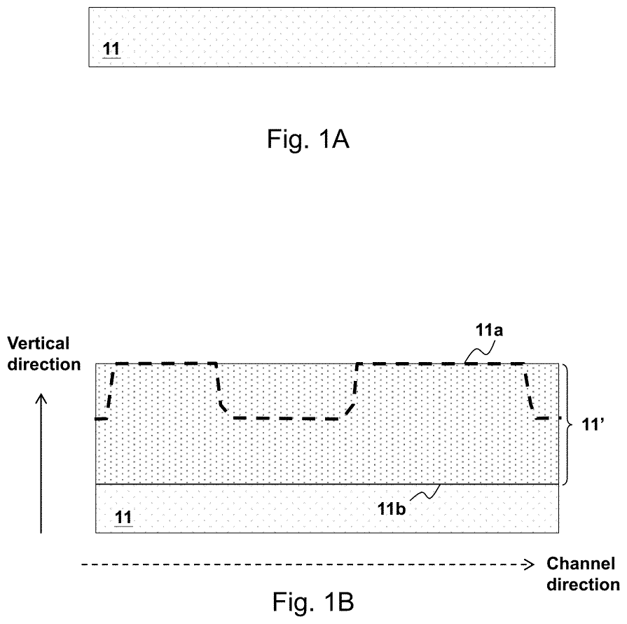

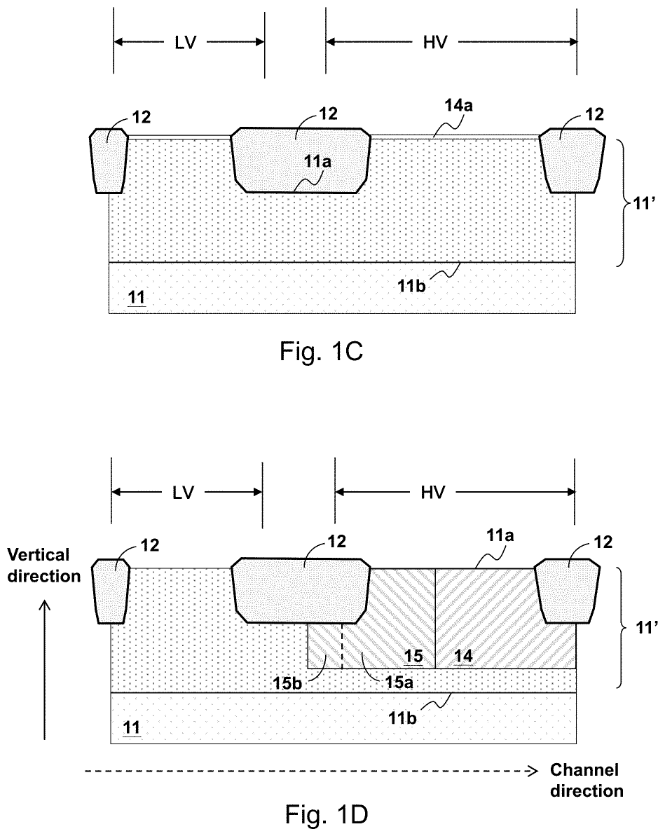

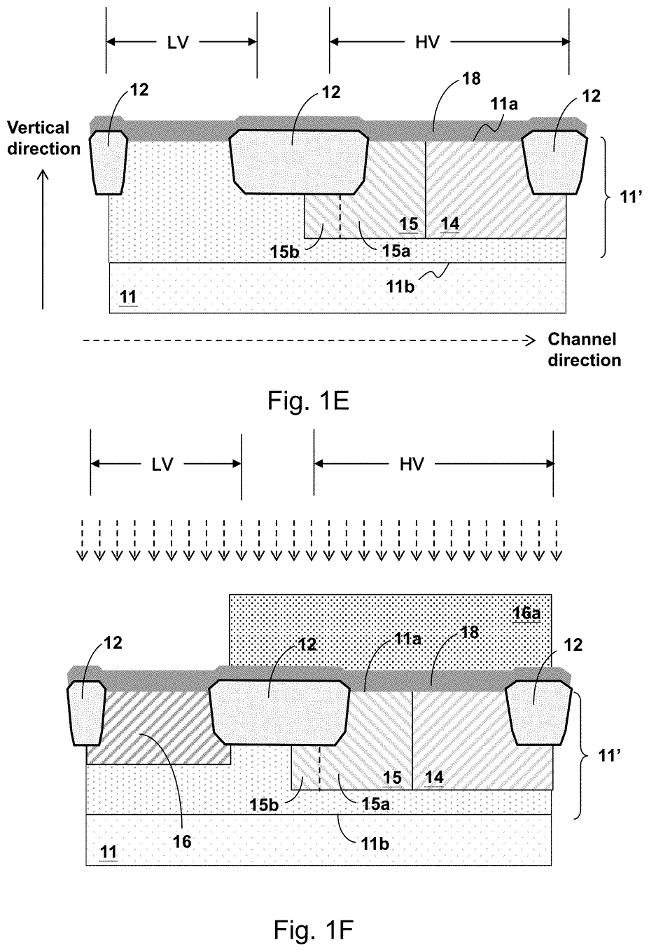

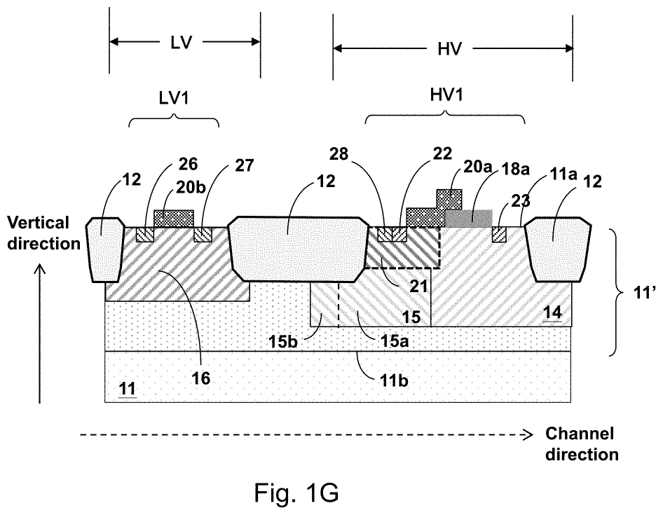

Please refer to FIG. 1A to FIG. 1G, which show a first embodiment of the present invention. FIG. 1A to FIG. 1G show cross-section views of an integration manufacturing method of a high voltage device and a low voltage device of the present invention.

As shown in FIG. 1A, a substrate 11 is provided. The substrate 11 is, for example but not limited to, a P-type or N-type semiconductor substrate. A high voltage device and a low voltage device are to be formed in the substrate 11.

Next, referring to FIG. 1B, a semiconductor layer 11′ is formed on the substrate 11. The semiconductor layer 11′ has a top surface 11a and a bottom surface 11b opposite to the top surface 11a in a vertical direction (as indicated by the direction of the solid arrow in FIG. 1B). At this moment, because the insulation regions 12 have not yet been formed on the semiconductor layer 11′, the top surface 11a has not yet been entirely defined. Subsequent to the formation of the insulation regions 12 on the semiconductor layer 11′, the top surface 11a will be as shown by a thick dashed line in FIG. 1B. The semiconductor layer 11′, for example, is formed on the substrate 11 by an epitaxial process step, or is a part of the substrate 11. The semiconductor layer 11′ can be formed by various methods known to a person having ordinary skill in the art, so the details thereof are not redundantly explained here.

In one embodiment, the semiconductor layer 11′ is a P-type semiconductor epitaxial layer having a volume resistance of 45 Ohm-cm.

Next, referring to FIG. 1C, the insulation regions 12 are formed on the semiconductor layer 11′, for defining a high voltage device region HV and a low voltage device region LV. The insulation regions 12 can be, for example but not limited to, a shallow trench isolation (STI) structure or a local oxidation of silicon (LOCOS) structure. Referring still to FIG. 1C, subsequent to the formation of the insulation regions 12, a sacrificial oxide layer 14a is formed on the top surface 11a of the semiconductor layer 11′, wherein the sacrificial oxide layer 14a serves as a block layer during an ion implantation process step for forming a first high voltage well 14 and a second high voltage well 15, thereby preventing the semiconductor layer 11′ from being directly bombarded, so that no defect will occur in the semiconductor layer 11′.

Next, referring to FIG. 1D, first conductivity type impurities are doped in the semiconductor layer 11′ by at least one ion implantation process step, to form the first high voltage well 14. The first high voltage well 14 is formed in the high voltage device region HV in the semiconductor layer 11′. The first high voltage well 14 has the first conductivity type, and is located below and in contact with the top surface 11a in the vertical direction. Apart of the first high voltage well 14 defines a drift region, which serve as a drift current channel in an ON operation of the high voltage device in the high voltage device region HV.

Please still refer to FIG. 1D. Second conductivity type impurities are doped in the semiconductor layer 11′ by at least one ion implantation process step, to form the second high voltage well 15 in the semiconductor layer 11′. The second high voltage well 15 has the second conductivity type, and is located below and in contact with the top surface 11a in the vertical direction. The first high voltage well 14 and the second high voltage well 15 are connected to each other in a channel direction (as indicated by the direction of the dashed arrow shown in FIG. 1D). The second high voltage well 15 has a first portion 15a and a second portion 15b, wherein the first portion 15a is located in the high voltage device region HV, whereas the second portion 15b is located between the high voltage device region HV and the low voltage device region LV.

Next, referring to FIG. 1E, subsequent to the formation of the first high voltage well 14 and the second high voltage well 15, an oxide layer 18 is formed on the semiconductor layer 11′. The oxide layer 18 overlays the high voltage device region HV and the low voltage device region LV. The oxide layer 18 can be formed by, for example but not limited to, a chemical vapor deposition (CVD) process step.

In one preferred embodiment, the oxide layer 18 has a thickness ranging between 400 Å and 450 Å.

Next, referring to FIG. 1F, subsequent to the formation of the oxide layer 18, a first low voltage well 16 can be formed by steps including, for example but not limited to, a lithography process step and an ion implantation step, wherein the lithography process step forms a photo-resist layer 16a as a mask and the ion implantation step dopes first conductivity type impurities in the low voltage device region LV in the semiconductor layer 11′, to form the first low voltage well 16. In this embodiment, the first low voltage well 16 can be formed by, for example but not limited to, an ion implantation process step, which implants first conductivity type impurities in a defined region for the first low voltage well 16 in the semiconductor layer 11′ in the form of accelerated ions (as indicated by dashed arrows shown in FIG. 1F) which penetrate the oxide layer 18, to form the first low voltage well 16.

Next, referring to FIG. 1G, a reduced surface field (RESURF) oxide region 18a, a high voltage gate 20a, a body region 21, a high voltage source 22, a high voltage drain 23 and a body contact 28 are formed, so as to form a high voltage device HV1 in the high voltage device region HV. That is, the high voltage device HV1 includes: the first high voltage well 14, a first portion 15a of the second high voltage well 15, the RESURF oxide region 18a, the high voltage gate 20a, the body region 21, the high voltage source 22, the high voltage drain 23 and the body contact 28.

In one embodiment, the RESURF oxide region 18a is formed by etching the oxide layer 18. The RESURF oxide region 18a is formed on and in contact with the top surface 11a. The RESURF oxide region 18a serves to reduce surface electric field in an OFF operation of the high voltage device HV1, so as to enhance its breakdown voltage.

A part of the body region 21 is located vertically below the high voltage gate 20a and near the top surface 11a, wherein the part of the body region 21 serves as an inversion region of the high voltage device region HV, so as to provide an inversion current channel of the high voltage device HV1.

Please still refer to FIG. 1G. A first low voltage gate 20b, a first low voltage source 26 and a first low voltage drain 27 are formed in the low voltage device region LV, so as to form a low voltage device LV1. That is, the low voltage device LV1 includes: a first low voltage well 16, the first low voltage gate 20b, the first low voltage source 26 and the first low voltage drain 27.

Apart of the first low voltage well 16 serves as an inversion region of the low voltage device region LV, so as to provide an inversion current channel of the low voltage device LV1. In this embodiment, the first low voltage well 16 has the first conductivity type, whereas, each of the first low voltage source 26 and the first low voltage drain 27 has the second conductivity type. In another embodiment, the first low voltage well 16 has the second conductivity type, whereas, each of the first low voltage source 26 and the first low voltage drain 27 has the first conductivity type.

In one embodiment, the gate driving voltage of the high voltage device HV1 in the high voltage device region HV is 3.3V.

In one embodiment, the body region 21 is formed via a self-alignment process step.

Note that the term “inversion current channel” means thus. Taking this embodiment as an example, when the high voltage device operates in ON operation due to the voltage applied to the gate, an inversion layer is formed below the gate, so that a conduction current flows through the region of the inversion layer, which is the inverse current channel known to a person having ordinary skill in the art, so the details thereof are not redundantly explained here. The same definition of the term “inversion current channel” is applied to other embodiments in the present invention.

Note that the first conductivity type and the second conductivity type can be P-type or N-type. For example, when the first conductivity type is P-type, the second conductivity type is N-type. For another example, when the first conductivity type is N-type, the second conductivity type is P-type.

Note that the term “drift current channel” means thus. Taking this embodiment as an example, the drift region provides a region where the conduction current passes through in a drifting manner when the high voltage device HV1 operates in the ON operation, and the current path through the drift region is referred to as the “drift current channel”, which is known to a person having ordinary skill in the art, so the details thereof are not redundantly explained here.

Note that the top surface 11a as referred to does not mean a completely flat plane but refers to the surface of the semiconductor layer 11′. In the present embodiment, for example, a part of the top surface 11a where the insulation region 12 is in contact with the semiconductor layer 11′ has a recessed portion.

Note that the gate includes a dielectric layer in contact with the top surface, a conductive layer, and a spacer layer which is insulative. The conductive layer serves as an electrical contact of the gate, and is formed on and is in contact with the dielectric layer. The spacer layer is formed out of two sides of the conductive layer, as an electrical insulative layer of the gate.

In addition, the term “high voltage device” refers to a transistor device wherein a voltage applied to the drain thereof in normal operation is higher than a specific voltage, such as 5V. A lateral distance between the body region 21 and the drain 23 (length of the drift region) of the high voltage device is determined according to the required operation voltage during normal operation, so that the device can operate at or higher than the aforementioned specific voltage, which is known to a person having ordinary skill in the art, so the details thereof are not redundantly explained here.

On the contrary, the term “low voltage device” refers to a transistor device wherein a voltage applied to the drain thereof in normal operation is not higher than a specific voltage, such as 5V, which is known to a person having ordinary skill in the art, so the details thereof are not redundantly explained here.

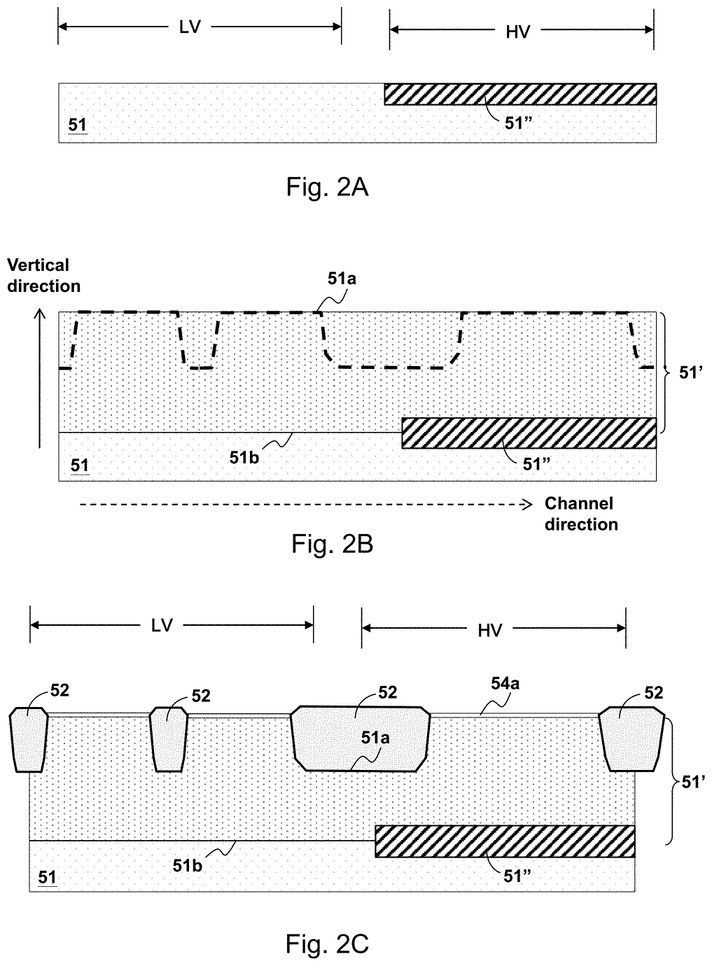

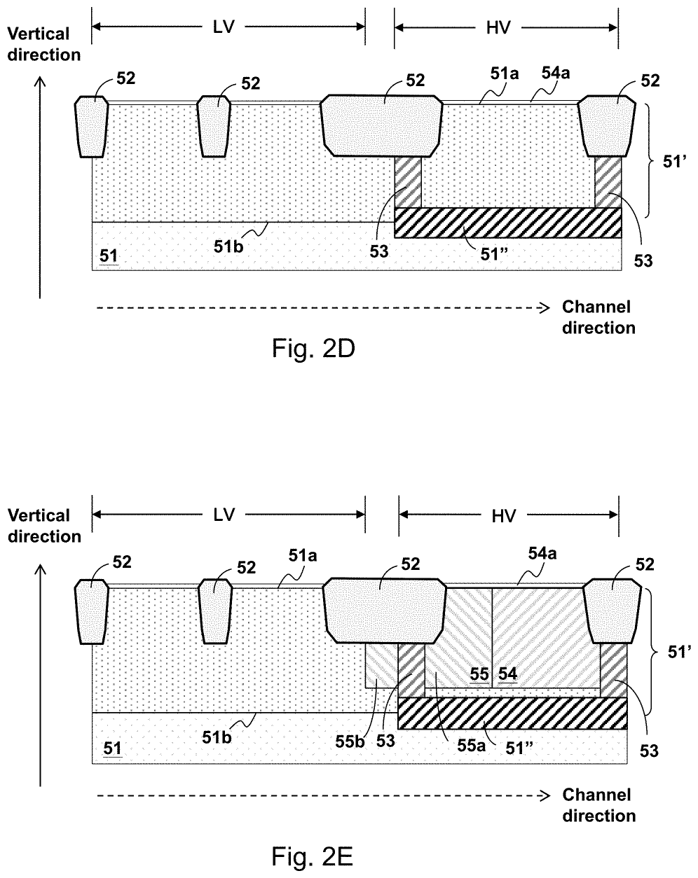

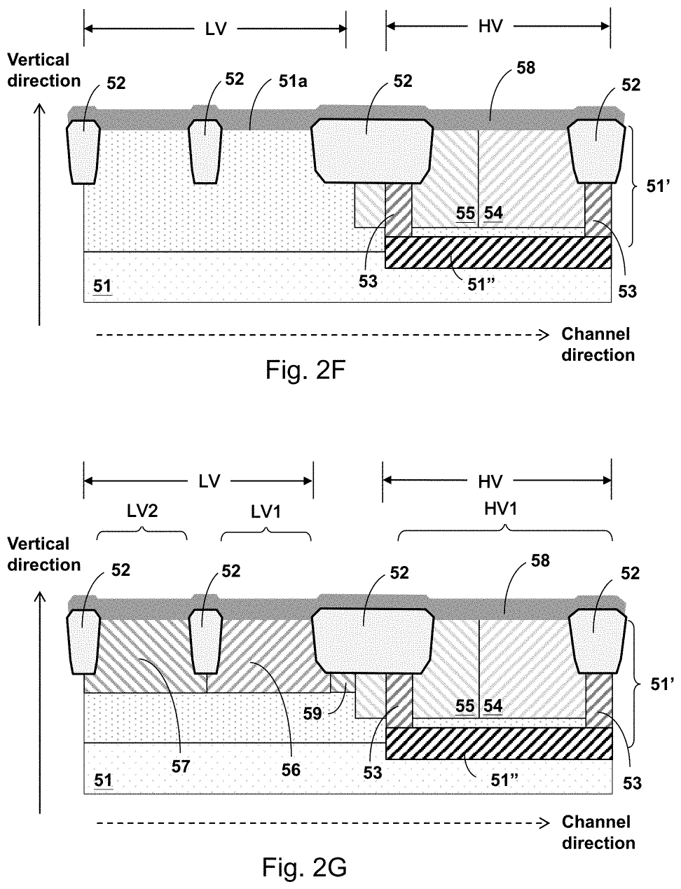

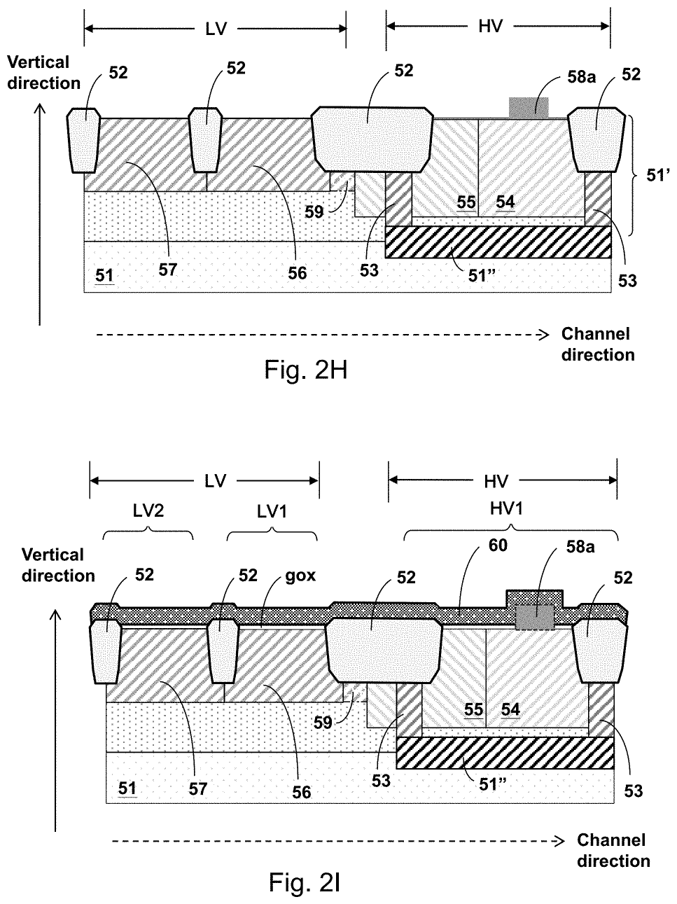

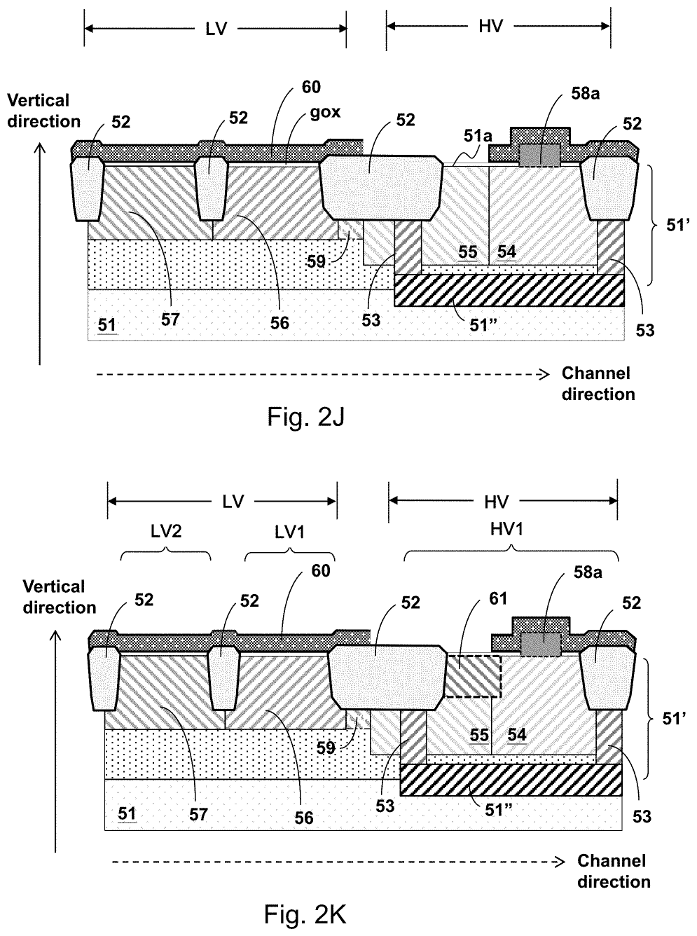

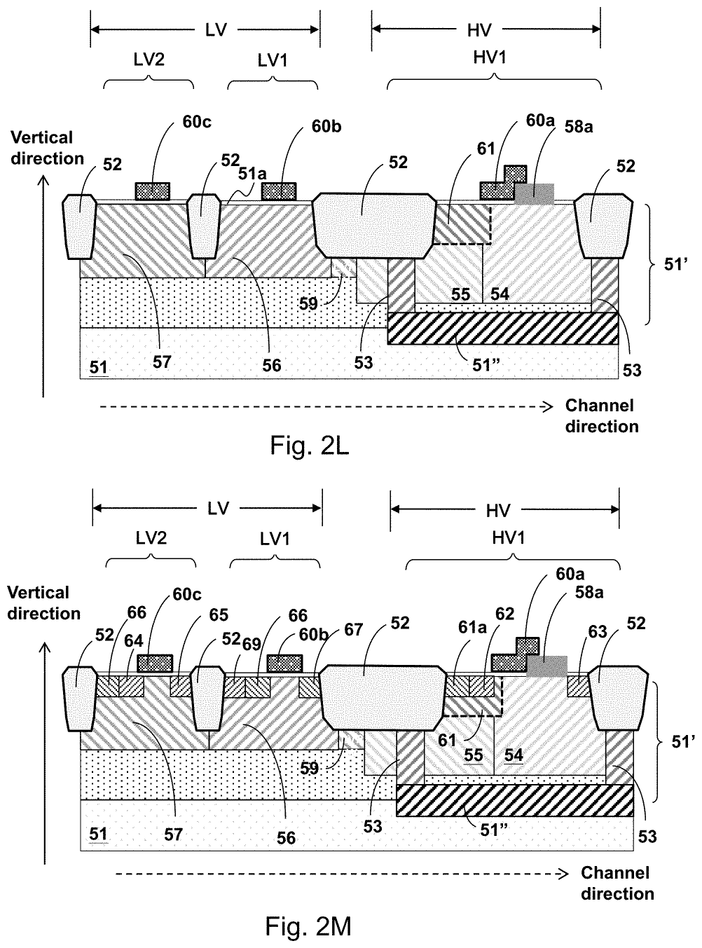

Please refer to FIG. 2A to FIG. 2M, which show a second embodiment of the present invention. FIG. 2A to FIG. 2M show cross-section views of an integration manufacturing method of a high voltage device and a low voltage device of the present invention.

As shown in FIG. 2A, a substrate 51 is provided. The substrate 51 is, for example but not limited to, a P-type or N-type semiconductor substrate. A high voltage device and at least one low voltage device are to be formed in the substrate 51.

Please still refer to FIG. 2A. A buried layer 51″ is formed in the high voltage device region HV in the substrate 51, wherein the buried layer 51″ has a first conductivity type. The buried layer 51″ can be formed by, for example but not limited to, an ion implantation process step, which implants first conductivity type impurities in the substrate 51 in the form of accelerated ions, to form the buried layer 51″. For example, in a case wherein the semiconductor layer 51′ is an epitaxial layer, In one embodiment, the buried layer 51″ can be formed by process steps as below. First, prior to the formation of the epitaxial layer, first conductivity type impurities can be implanted in the substrate 51 in the form of accelerated ions by an ion implantation process step. Subsequently, the epitaxial layer is formed by an epitaxial layer process step, so that the epitaxial layer serves as the semiconductor layer 51′ (referring to FIG. 2B). Subsequently, a thermal process step diffuses a part of the first conductivity type impurities into the semiconductor layer 51′ to form the buried layer 51″.

Next, referring to FIG. 2B, a semiconductor layer 51′ is formed on the substrate 51. The semiconductor layer 51′ has a top surface 11a and a bottom surface 51b opposite to the top surface 51a in a vertical direction (as indicated by the direction of the solid arrow in FIG. 2B). At this moment, because the insulation regions 52 have not yet been formed on the semiconductor layer 51′, the top surface 51a has not yet been entirely defined. Subsequent to the formation of the insulation regions 52 on the semiconductor layer 51′, the top surface 51a will be as shown by the thick dashed line in FIG. 2B. The semiconductor layer 51′, for example, is formed on the substrate 51 by an epitaxial process step, or is a part of the substrate 51. The semiconductor layer 51′ can be formed by various methods known to a person having ordinary skill in the art, so the details thereof are not redundantly explained here.

In one embodiment, the semiconductor layer 51′ is a P-type semiconductor epitaxial layer having a volume resistance of 45 Ohm-cm.

Next, referring to FIG. 2C, the insulation regions 52 are formed on the semiconductor layer 51′, for defining a high voltage device region HV and a low voltage device region LV. The insulation regions 12 can be, for example but not limited to, a shallow trench isolation (STI) structure or a local oxidation of silicon (LOCOS) structure. Referring still to FIG. 2C, subsequent to the formation of the insulation regions 52, a sacrificial oxide layer 54a is formed on the top surface 51a of the semiconductor layer 51′, wherein the sacrificial oxide layer 54a serves as a block layer during an ion implantation process step for forming a first high voltage well 54 and a second high voltage well 55, thereby preventing the semiconductor layer 51′ from being directly bombarded, so that no defect will occur in the semiconductor layer 51′.

Next, referring to FIG. 2D, first conductivity type impurities are doped in the semiconductor layer 51′ by at least one ion implantation process step, to form a deep well 53. The deep well 53 has the first conductivity type, and wherein the deep well 53 is in contact with the insulation regions 12 and the buried layer 51″ which define the high voltage device region HV.

Next, referring to FIG. 2E, first conductivity type impurities are doped in the semiconductor layer 51′ by at least one ion implantation process step, to form the first high voltage well 54. The first high voltage well 54 is formed in the high voltage device region HV in the semiconductor layer 51′. The first high voltage well 54 has the first conductivity type, and is located below and in contact with the top surface 51a in the vertical direction. Apart of the first high voltage well 54 defines a drift region, which serve as a drift current channel in an ON operation of the high voltage device in the high voltage device region HV.

Please still refer to FIG. 2E. Second conductivity type impurities are doped in the semiconductor layer 51′ by at least one ion implantation process step, to form the second high voltage well 55. The second high voltage well 55 is formed in the semiconductor layer 51′. The second high voltage well 55 has the second conductivity type, and is located below and in contact with the top surface 51a in the vertical direction. The first high voltage well 54 and the second high voltage well 55 are connected to each other in a channel direction (as indicated by the direction of the dashed arrow shown in FIG. 2E). The second high voltage well 55 has a first portion 55a and a second portion 55b, wherein the first portion 55a is located in the high voltage device region HV, whereas the second portion 55b is located between the high voltage device region HV and the low voltage device region LV.

The second portion 55b of the second high voltage well 55, the buried layer 51″ and the deep well 53 constitute an isolation region, which serves to electrically isolate the high voltage device region HV from the low voltage device region LV in the semiconductor layer 51′.

Next, referring to FIG. 2F, subsequent to the formation of the first high voltage well 54 and the second high voltage well 55, an oxide layer 58 is formed on the semiconductor layer 51′. The oxide layer 58 overlays the high voltage device region HV and the low voltage device region LV. The oxide layer 58 can be formed by, for example but not limited to, a chemical vapor deposition (CVD) process step.

In one embodiment, the oxide layer 58 has a thickness ranging between 400 Å and 450 Å.

Next, referring to FIG. 2G, subsequent to the formation of the oxide layer 58, a first low voltage well 56 can be formed by steps including, for example but not limited to, a lithography process step and an ion implantation step, wherein the lithography process step forms a photo-resist layer (not shown) as a mask and the ion implantation step dopes first conductivity type impurities in the low voltage device region LV in the semiconductor layer 51′, to form the first low voltage well 56. In this embodiment, the first low voltage well 56 can be formed by, for example but not limited to, an ion implantation process step which implants first conductivity type impurities in a defined region for the first low voltage well 56 in the semiconductor layer 51′ in the form of accelerated ions which penetrate the oxide layer 58, to form the first low voltage well 56.

Next, please still refer to FIG. 2G. Subsequent to the formation of the oxide layer 58, a second low voltage well 16 can be formed by steps including, for example but not limited to, a lithography process step and an ion implantation step, wherein the lithography process step forms a photo-resist layer (not shown) as a mask and the ion implantation step dopes second conductivity type impurities in the low voltage device region LV in the semiconductor layer 51′, to form the second low voltage well 57. In this embodiment, the second low voltage well 57 can be formed by, for example but not limited to, an ion implantation process step which implants second conductivity type impurities in a defined region for the second low voltage well 57 in the semiconductor layer 51′ in the form of accelerated ions which passes through the oxide layer 58, to form the second low voltage well 57.

In this embodiment, the low voltage device region LV includes: a first low voltage device LV1 and a second low voltage device LV2. The first low voltage well 56 and the second low voltage well 57 are in contact with each other in the channel direction. The first low voltage device LV1 and the second low voltage device LV2 have conductivity types opposite to each other.

Next, please still refer to FIG. 2G. In this embodiment, a low voltage isolation region 59 is formed by adopting the same ion implantation process step as the one which forms the second low voltage well 57. The low voltage isolation region 59 has the second conductivity type and serves as apart of the above-mentioned isolation region. That is, the above-mentioned isolation region further includes the low voltage isolation region 59. In this embodiment, the isolation region includes: a second portion 55b, a buried layer 51″, a deep well 53 and the low voltage isolation region 59, so that the isolation region serves to electrically isolate the high voltage device region HV from the low voltage device region LV in the semiconductor layer 51′.

Next, referring to FIG. 2H, subsequent to the formation of the first low voltage well 56 and the second low voltage well 57, by a lithography process step and an etching process step, the oxide layer 58 is etched to form a RESURF oxide region 58a in the high voltage device region HV. In this embodiment, the RESURF oxide region is formed by etching the oxide layer 58. The RESURF oxide region is formed on and in contact with the top surface 51a of the high voltage device region HV. The RESURF oxide region 58a serves to reduce surface electric field in an OFF operation of the high voltage device HV1, so as to enhance its breakdown voltage.

Next, referring to FIG. 2I, subsequent to the formation of the RESURF oxide region 58a, a gate oxide layer gox is formed on the semiconductor layer 51′, wherein the gate oxide layer gox is in contact with the semiconductor layer 51′. The gate oxide layer gox overlays the high voltage device region HV and the low voltage device region LV. In one embodiment, the gate oxide layer gox has a thickness ranging between 80 Å and 100 Å.

Please still refer to FIG. 2I. A polysilicon layer 60 is formed on the gate oxide layer gox, wherein the polysilicon layer 60 is in contact with the gate oxide layer gox.

Next, referring to FIG. 2J, by a lithography process step and an etching process step, the polysilicon layer 60 is etched to form a mask for a defined region of the body region 61 in the high voltage device region HV in the semiconductor layer 51′.

Next, referring to FIG. 2K, a body region 61 is formed in the high voltage device region HV in the semiconductor layer 51′, wherein the body region 61 and the first high voltage well 54 are in contact with each other in the channel direction.

The body region 61 can be formed by, for example but not limited to, an ion implantation process step which uses the defined region of the polysilicon layer 60 as a mask and dopes second conductivity type impurities in the semiconductor layer 51′ in the form of accelerated ions, to form the body region 61.

Next, referring to FIG. 2L, the polysilicon layer 60 is etched by the lithography process step and the etching process step, so as to form a high voltage gate 60a in the high voltage device HV1 in the high voltage device region HV, a first low voltage gate 60b in the first low voltage device LV1 in the low voltage device region LV, and a second low voltage gate 60c in the second low voltage device LV2 in the low voltage device region LV. Each of the gate 60a, the gate 60b and the gate 60c has its own dielectric layer and conductive layer formed on the top surface 51a of the semiconductor layer 51′ in the vertical direction (as indicated by the direction of the solid arrow in FIG. 2L). Apart of the body region 61 is located vertically below the gate 60a, wherein the part of the body region 61 serves to provide an inversion region in an ON operation of the high voltage device HV1.

Next, referring to FIG. 2M, a high voltage source 62 and a high voltage drain 63 are formed in the semiconductor layer 51′, wherein the high voltage source 62 and the high voltage drain 63 are located below and outside two sides of the high voltage gate 60a respectively, wherein the side of the high voltage gate 60a which is closer to the high voltage source 62 is a source side and the side of the high voltage gate 60a which is closer to the high voltage drain 63 is a drain side, and wherein the high voltage source 62 is located in the body region 61, and the high voltage drain 63 is located in the first high voltage well 54 outside the drain side. In the channel direction, the drift region is located in the first high voltage well 54 between the high voltage drain 63 and the body region 61, wherein each of the high voltage source 62 and the high voltage drain 63 has the first conductivity type.

Please still refer to FIG. 2M. a first low voltage source 66 and a first low voltage drain 67 are formed in the low voltage device LV1 in the low voltage device region LV in the semiconductor layer 51′, wherein the first low voltage source 66 and the first low voltage drain 67 are located below and outside two sides of the low voltage gate 60b respectively, wherein the side of the low voltage gate 60b which is closer to the first low voltage source 66 is a source side and the side of the low voltage gate 60b which is closer to the first low voltage drain 67 is a drain side, and wherein the first low voltage source 66 is located in the first low voltage well 56, and the first low voltage drain 67 is located in the first low voltage well 56 outside the drain side.

Please still refer to FIG. 2M. A second low voltage source 64 and a second low voltage drain 65 are formed in the second low voltage device LV2 in the low voltage device region LV in the semiconductor layer 51′, wherein the second low voltage source 64 and the second low voltage drain 65 are located below and outside two sides of the low voltage gate 60c respectively, wherein the side of the low voltage gate 60c which is closer to the second low voltage source 64 is a source side and the side of the low voltage gate 60c which is closer to the second low voltage drain 65 is a drain side, and wherein the second low voltage source 64 is located in the second low voltage well 57, and the second low voltage drain 65 is located in a second low voltage well 57 outside the drain side.

In this embodiment, the low voltage device region LV includes: a first low voltage device LV1 and a second low voltage device LV2. The first low voltage device LV1 includes: the first low voltage well 56, the first low voltage gate 60b, the first low voltage source 66 and the first low voltage drain 67. The second low voltage device LV2 includes: the second low voltage well 57, the second low voltage gate 60c, the second low voltage source 64 and the second low voltage drain 65. The first low voltage well 56 and the second low voltage well 57 are in contact with each other in the channel direction. The first low voltage device LV1 and the second low voltage device LV2 have conductivity types opposite to each other. The second low voltage source 64, the second low voltage drain 65, the high voltage source 62 and the high voltage drain 63 are formed at the same time by one same ion implantation process step.

In this embodiment, the first low voltage device LV1 further includes a first low voltage well contact 69 having the first conductivity type, wherein the first low voltage well contact 69 serves as an electrical contact of the first low voltage well 56. The second low voltage device LV2 further includes a second low voltage well contact 66 having the second conductivity type, wherein the second low voltage well contact 66 serves as an electrical contact of the second low voltage well 57.

In this embodiment, the gate driving voltage of the high voltage device HV1 in the high voltage device region HV is 3.3V.

In this embodiment, the body region 61 is formed via a self-alignment process step.

In this embodiment, each of the first low voltage gate 60b and the second low voltage gate 60c has a length greater than or equal to 0.18 micrometer, wherein each of the first low voltage device LV1 and the second low voltage device LV2 has a minimum feature size of 0.18 micrometer.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a lightly doped drain (LDD) may be added. For another example, the lithography process step is not limited to the mask technology but it can also include electron beam lithography. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. An integration manufacturing method of a high voltage device and a low voltage device, comprising:
providing a substrate;
forming a semiconductor layer on the substrate;
forming a plurality of insulation regions on the semiconductor layer, for defining a high voltage device region and a low voltage device region;
forming a first high voltage well having a first conductivity type in the high voltage device region in the semiconductor layer, wherein a part of the first high voltage well defines adrift region, which serve as a drift current channel in an ON operation of the high voltage device;
forming a second high voltage well having a second conductivity type in the semiconductor layer, wherein the first high voltage well and the second high voltage well are in contact with each other in a channel direction;
wherein the second high voltage well has a first portion and a second portion, wherein the first portion is located in the high voltage device region, and the second portion is located between the high voltage device region and the low voltage device region;
subsequent to the formation of the first high voltage well and the second high voltage well, forming an oxide layer on the semiconductor layer, wherein the oxide layer overlays the high voltage device region and the low voltage device region; and
subsequent to the formation of the oxide layer, forming a first low voltage well in the low voltage device region in the semiconductor layer;
wherein the first low voltage well is formed by implanting impurities in a defined region of the first low voltage well in a form of accelerated ions which penetrate the oxide layer.

2. The integration manufacturing method of the high voltage device and the low voltage device of claim 1, further comprising:
forming a buried layer in the high voltage device region in the substrate, wherein the buried layer has the first conductivity type; and
forming a deep well in the semiconductor layer, wherein the deep well has the first conductivity type, and wherein the deep well is in contact with the plurality of insulation regions and the buried layer which define the high voltage device region;
wherein the second portion of the second high voltage well, the buried layer and the deep well constitute an isolation region, which serves to electrically isolate the high voltage device region from the low voltage device region in the semiconductor layer.

3. The integration manufacturing method of the high voltage device and the low voltage device of claim 2, further comprising:
subsequent to the formation of the first low voltage well, etching the oxide layer to form a reduced surface field (RESURF) oxide region in the high voltage device region;
subsequent to the formation of the RESURF oxide region, forming a gate oxide layer on the semiconductor layer, wherein the gate oxide layer is in contact with the semiconductor layer, wherein the gate oxide layer overlays the high voltage device region and the low voltage device region;
forming a polysilicon layer on the gate oxide layer, wherein the polysilicon layer is in contact with the gate oxide layer; and
forming a body region in the high voltage device region in the semiconductor layer, wherein the body region and the first high voltage well are in contact with each other in the channel direction.

4. The integration manufacturing method of the high voltage device and the low voltage device of claim 3, further comprising:
etching the polysilicon layer to form a high voltage gate in the high voltage device region and a first low voltage gate in the low voltage device region.

5. The integration manufacturing method of the high voltage device and the low voltage device of claim 4, further comprising:
forming a high voltage source and a high voltage drain in the semiconductor layer, wherein the high voltage source and the high voltage drain are located below and outside two sides of the high voltage gate respectively, wherein the side of the high voltage gate which is closer to the high voltage source is a source side and the side of the high voltage gate which is closer to the high voltage drain is a drain side, and wherein the high voltage source is located in the body region, and the high voltage drain is located in the first high voltage well outside the drain side;
wherein in the channel direction, the drift region is located in the first high voltage well between the high voltage drain and the body region, wherein each of the high voltage source and the high voltage drain has the first conductivity type.

6. The integration manufacturing method of the high voltage device and the low voltage device of claim 5, further comprising:
forming a first low voltage source and a first low voltage drain in the low voltage device region in the semiconductor layer, wherein the first low voltage source and the first low voltage drain are located below and outside two sides of the low voltage gate respectively, wherein the side of the low voltage gate which is closer to the first low voltage source is a source side and the side of the low voltage gate which is closer to the first low voltage drain is a drain side, and wherein the first low voltage source is located in the first low voltage well, and the first low voltage drain is located in the first low voltage well outside the drain side.

7. The integration manufacturing method of the high voltage device and the low voltage device of claim 6, further comprising:
forming a second low voltage source and a second low voltage drain in the semiconductor layer, wherein the second low voltage source and the second low voltage drain are located below and outside two sides of the low voltage gate respectively, wherein the side of the low voltage gate which is closer to the second low voltage source is a source side and the side of the low voltage gate which is closer to the second low voltage drain is a drain side, and wherein the second low voltage source is located in the second low voltage well, and the second low voltage drain is located in a second low voltage well outside the drain side.

8. The integration manufacturing method of the high voltage device and the low voltage device of claim 7, wherein the low voltage device region includes a first low voltage device and a second low voltage device;
wherein the first low voltage device includes: the first low voltage well, the first low voltage gate, the first low voltage source and the first low voltage drain;
wherein the second low voltage device includes: the second low voltage well, the second low voltage gate, the second low voltage source and the second low voltage drain;
wherein the first low voltage well and the second low voltage well are in contact with each other in the channel direction;
wherein the first low voltage device and the second low voltage device have conductivity types opposite to each other;
wherein the second low voltage source, the second low voltage drain, the high voltage source and the high voltage drain are formed at the same time via one same ion implantation process step.

9. The integration manufacturing method of the high voltage device and the low voltage device of claim 1, wherein the semiconductor layer is a P-type semiconductor epitaxial layer having a volume resistance of 45 Ohm-cm.

10. The integration manufacturing method of the high voltage device and the low voltage device of claim 1, wherein the RESURF oxide region has a thickness ranging between 400 Å and 450 Å.

11. The integration manufacturing method of the high voltage device and the low voltage device of claim 3, wherein the gate oxide layer has a thickness ranging between 80 Å and 100 Å.

12. The integration manufacturing method of the high voltage device and the low voltage device of claim 1, wherein a gate driving voltage of a high voltage device in the high voltage device region is 3.3V.

13. The integration manufacturing method of the high voltage device and the low voltage device of claim 3, wherein the body region is formed via a self-alignment process step.

14. The integration manufacturing method of the high voltage device and the low voltage device of claim 8, wherein each of the first low voltage gate and the second low voltage gate has a length greater than or equal to 0.18 micrometer, and wherein each of the first low voltage device and the second low voltage device has a minimum feature size of 0.18 micrometer.
